(19) United States
(12) Patent Application Publication
(10) Pub. No.: US 2025/0246475 A1
(43) Pub. Date: Jul. 31, 2025

(54) CARRIER SUBSTRATE AND METHOD OF MANUFACTURING SEMICONDUCTOR PACKAGE USING THE SAME

(71) Applicant: SAMSUNG ELECTRONICS CO., LTD., SUWON-SI (KR)

(72) Inventors: Hyeongjin Hwang, Suwon-si (KR); Jihye Shim, Suwon-si (KR); Youngkwan Seo, Suwon-si (KR); Seonghyun Yoo, Suwon-si (KR)

(21) Appl. No.: 19/020,468

(22) Filed: Jan. 14, 2025

(30) Foreign Application Priority Data
Jan. 31, 2024 (KR) 10-2024-0015186

(51) Int. Cl. H01L 21/683

(52) U.S. Cl. CPC H01L 21/6835

(57) ABSTRACT

A carrier substrate includes a main body portion that includes a plate having an upper surface and a lower surface disposed opposite to the upper surface, and a groove formed in the lower surface of the plate, the main body portion having a first coefficient of thermal expansion, and a carrier block detachably mounted in the groove and having a second coefficient of thermal expansion different from the first coefficient of thermal expansion.

### CROSS-REFERENCE TO RELATED APPLICATION

This application is based on and claims priority under 35 U.S.C. § 119 to Korean Patent Application No. 10-2024-0015186, filed on Jan. 31, 2024, in the Korean Intellectual Property Office, the disclosure of which is incorporated by reference herein in its entirety.

### BACKGROUND

### 1. Technical Field

The inventive concept relates to a carrier substrate, and more particularly, to a carrier substrate having an adjustable coefficient of thermal expansion, and a method of manufacturing a semiconductor package using the same.

### 2. Discussion of Related Art

Semiconductor devices can be formed by repeatedly performing a series of semiconductor processes on a silicon wafer substrate. A wafer on which the semiconductor devices are formed can be separated into a plurality of chips through a dicing process or a singulation process. The separated chips can be mounted on a substrate such as a lead frame, a printed circuit board or a semiconductor wafer, through a die attach process.

In a semiconductor packaging process, a temperature change during processing can cause a warpage phenomenon in which a semiconductor package is bent. A carrier substrate having an appropriate coefficient of thermal expansion (CTE) may be used to inhibit warpage during a process.

### SUMMARY

The inventive concept provides a carrier substrate having an adjustable coefficient of thermal expansion. A carrier substrate having an adjustable coefficient of thermal expansion may be used to manufacture a semiconductor package having improved reliability. A carrier substrate having an adjustable coefficient of thermal expansion may be used to maintain process stability during the manufacture of a semiconductor package.

Also, the inventive concept is not limited to applications described herein, and other applications may be clearly understood by those skilled in the art from the description below.

According to an aspect of the inventive concept, there is provided a carrier substrate including a main body portion that includes a plate having an upper surface and a lower surface disposed opposite to the upper surface, and a groove formed in the lower surface of the plate, the main body portion having a first coefficient of thermal expansion; and a carrier block detachably mounted in the groove and having a second coefficient of thermal expansion different from the first coefficient of thermal expansion.

According to another aspect of the inventive concept, there is provided a carrier substrate including a main body portion that includes a plate capable of supporting a device substrate disposed on an upper surface of the plate and a plurality of grooves arranged radially symmetrical to each other on a lower surface of the plate disposed opposite to the upper surface of the plate, and the plurality of grooves being recesses in the lower surface of the plate in a thickness direction of the plate, the main body portion having a first coefficient of thermal expansion, a plurality of carrier blocks disposed in the plurality of grooves, respectively, and having a second coefficient of thermal expansion less than the first coefficient of thermal expansion, and an adhesive layer configured to fix the plurality of carrier blocks inside of the plurality of grooves.

According to another aspect of the inventive concept, there is provided a method of manufacturing a semiconductor package by using a carrier substrate, including preparing a carrier substrate including a main body portion that includes a plate capable of supporting a device substrate on an upper surface of the plate and a groove formed in a lower surface of the plate, the main body portion having a first coefficient of thermal expansion, mounting the device substrate on the upper surface of the plate, and mounting, in the groove of the main body portion, a carrier block having a second coefficient of thermal expansion different from the first coefficient of thermal expansion, wherein the main body portion and the carrier block have a combined coefficient of thermal expansion corresponding to a coefficient of thermal expansion of the device substrate.

### BRIEF DESCRIPTION OF THE DRAWINGS

Embodiments will be more clearly understood from the following detailed description taken in conjunction with the accompanying drawings in which:

FIG. 1 is a perspective view schematically illustrating a carrier substrate supporting a device substrate in the operation of manufacturing a semiconductor package according to an embodiment;

FIG. 2 is a perspective view illustrating a carrier substrate according to an embodiment;

FIG. 3 is a partial cross-sectional view illustrating a carrier substrate according to an embodiment;

FIG. 4 is a perspective view illustrating a carrier substrate according to an embodiment;

FIG. 5A and FIG. 5B are perspective views illustrating a carrier substrate according to an embodiment;

FIG. 6 is a perspective view illustrating a carrier substrate according to an embodiment;

FIG. 7A, FIG. 7B, and FIG. 7C are partial cross-sectional views schematically illustrating a process of a method of manufacturing a carrier substrate according to an embodiment; and

FIG. 8A, FIG. 8B, FIG. 8C, and FIG. 8E are partial cross-sectional views schematically illustrating a carrier substrate supporting a device substrate in a method of manufacturing a semiconductor package according to an embodiment.

### DETAILED DESCRIPTION

Embodiments are described below in detail with reference to the attached drawings. The same reference numerals are used for the same components in the drawings, and repeated descriptions thereof may be omitted.

The disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the disclosure. In the disclosure, certain detailed descriptions may be omitted when they serve to obscure the essence of the inventive concept.

One or more drawings may be depicted and/or described in the context of a first direction X and a second direction Y crossing the first direction X. For example, the first direction X and the second direction Y may be perpendicular to each other and define a plane. A direction normal to the plane, that is, a thickness direction may be a third direction Z. In other words, the third direction Z may be perpendicular to each of the first direction X and the second direction Y.

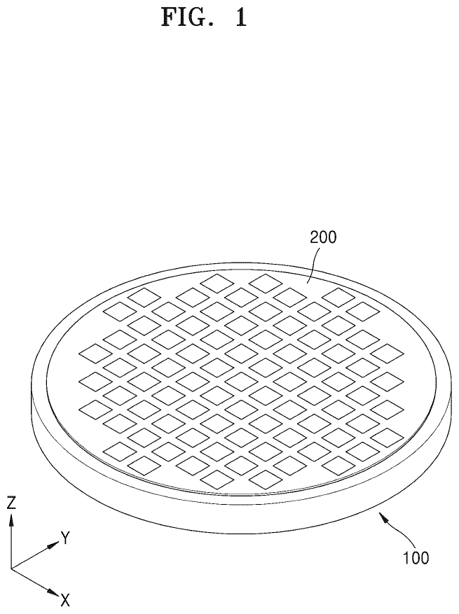

FIG. 1 is a perspective view schematically illustrating a carrier substrate in the operation of manufacturing a semiconductor package according to an embodiment.

Referring to FIG. 1, a carrier substrate 100 according to an embodiment may support a device substrate 200 in the operation of manufacturing a semiconductor package.

The carrier substrate 100 may include a substrate. The substrate may be used to support the device substrate 200 in a semiconductor manufacturing process. The device substrate 200 may be bonded to the carrier substrate 100 through a glue layer (not shown).

The semiconductor manufacturing process may be performed in a state where the device substrate 200 is bonded to the carrier substrate 100. For example, a thinning process of thinning the device substrate 200 may be performed in a state where the device substrate 200 is bonded to the carrier substrate 100. In another example, a redistribution process, an exposure process and development process using photoresists may be performed, or a plating process, may be performed in a state where the device substrate 200 is bonded to the carrier substrate 100.

The device substrate 200 may be debonded from the carrier substrate 100 after a process is performed. For reference, since the bonding between the device substrate 200 and the carrier substrate 100 may be released, is the bonding may be called a temporary bonding or a temporary wafer bonding.

Both the carrier substrate 100 and the device substrate 200 may have a disk shape. Accordingly, in some embodiments, the carrier substrate 100 and the device substrate 200 may be referred to as a carrier wafer and a device wafer, respectively. The carrier substrate 100 may have a greater diameter than the device substrate 200. The carrier substrate 100 may have a greater thickness than the device substrate 200. In some embodiments, the carrier substrate 100 may have substantially the same diameter as the device substrate 200. The carrier substrate 100 may have substantially the same thickness as the device substrate 200 before the device substrate 200 is thinned in a thinning process.

A method of manufacturing a semiconductor package by using the carrier substrate 100 of an embodiment may be a Wafer Support System (WSS) process. The WSS process may refer to a system in which a carrier wafer may be attached to a device wafer, and a back grinding process may be performed on the device wafer. Additional processes may be performed on a back grinded surface of the thinned device wafer. The WSS process may include a carrier bonding process of attaching the carrier wafer to the device wafer for a Through Silicon Via (TSV) package and a carrier debonding process of detaching the carrier wafer again after completing processes such as forming a bump on the back of the device wafer.

In the process of manufacturing a semiconductor package, a warpage phenomenon in which a device substrate is bent may occur. Warpage may occur due to a difference of a coefficient of thermal expansion (CTE) between individual components that constitute the semiconductor package. Further, temperatures used for different processes for manufacturing the semiconductor package may be different, and warpage may also occur due to a difference of a coefficient of thermal expansion between the carrier substrate and the device substrate. If warpage occurs during a process, the reliability of a subsequent semiconductor process or processes may decrease. For example, in the warpage is greater than a certain amount, the reliability of the subsequent semiconductor process or processes may decrease. Accordingly, a carrier substrate having an appropriate coefficient of thermal expansion may be used a given process, and different carrier substrate may be used for different processes.

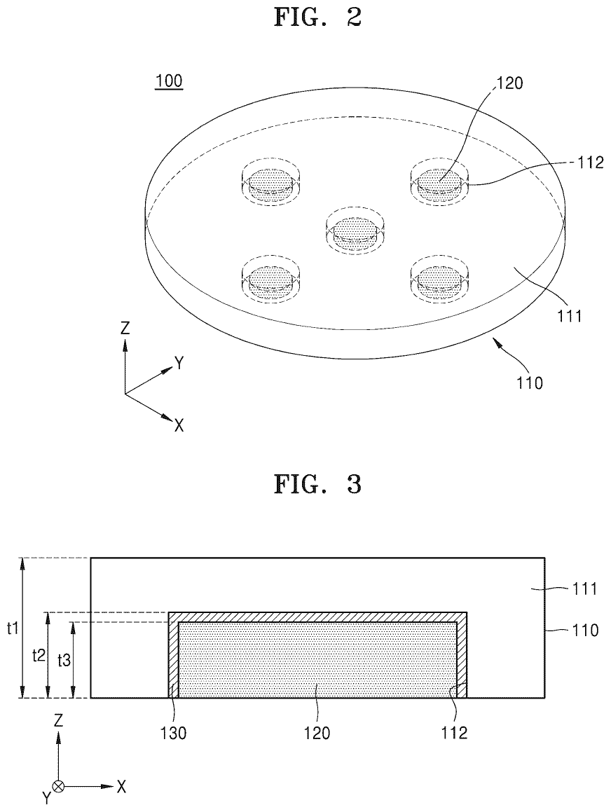

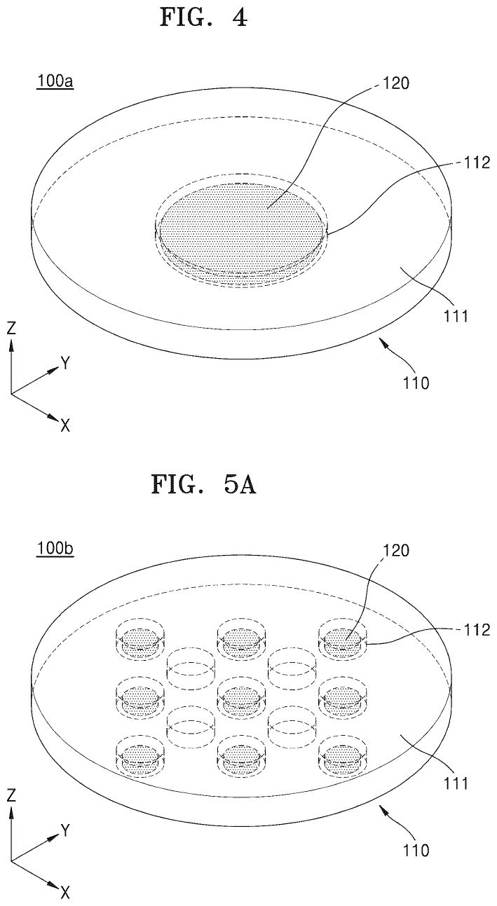

FIG. 2 is a perspective view illustrating a carrier substrate 100 according to an embodiment. FIG. 3 is a partial cross-sectional view illustrating the carrier substrate 100 according to an embodiment. Here, FIG. 3 is an enlarged cross-sectional view illustrating a portion of the carrier substrate 100. The carrier substrate 100 may include a groove 112. A carrier block 120 may be disposed in the groove 112. The carrier substrate 100 may include the groove 112 of a main body portion 110, and the carrier block 120 may be mounted in the groove 112. For example, an adhesive layer 130 may be disposed between the carrier block 120 and the main body portion 110. The adhesive layer 130 may couple the carrier block 120 and the main body portion 110. In the carrier substrate 100 of FIG. 2, the illustration of the adhesive layer 130 is omitted.

Referring to FIG. 1, FIG. 2, and FIG. 3, the carrier substrate 100 may include the main body portion 110, the carrier block 120, and the adhesive layer 130.

The main body portion 110 may include a plate 111. The plate 111 may support the device substrate 200. The plate 111 may be a disk-shaped substrate and may include an upper surface and a lower surface disposed opposite to each other. The device substrate 200 may be disposed on the upper surface of the plate 111. For example, the plate 111 may have a diameter that is the same as or greater than the device substrate 200, and the device substrate 200 may be disposed on the upper surface of the plate 111.

The main body portion 110 may include the groove 112 formed in the lower surface of the plate 111. The carrier block 120 may be mounted in the groove 112. The groove 112 may be formed by recessing the lower surface of the plate 111 in a thickness direction (the Z direction) of the plate 111. The lower surface of the plate 111 may be recessed to a depth t2 less than the thickness t1 of the plate 111. In other words, the groove 112 may be form in a portion of the plate 111, and may not penetrate through the plate 111. The groove 112 may be formed in the lower surface of the plate 111 toward the upper surface of the plate 111.

The groove 112 may be formed in a shape corresponding to the shape of the carrier block 120. The groove 112 may also be formed by being recessed in a shape corresponding to the shape and size of the carrier block 120 and the carrier block 120 may be mounted inside the groove 112. For example, when the carrier block 120 has a disk shape, the plate 111 may be etched in the disk shape to form the groove 112 formed in the disk shape. When the carrier block 120 has a square plate shape, the plate 111 may be etched in a square plate shape to form the groove 112 formed in the square plate shape. In another example, when the carrier block 120 has a cross shape, the plate 111 may be etched in the cross shape to form the groove 112 formed in the cross plate shape. In yet another embodiment, the carrier block 120 and the groove 112 may have complementary shapes, for example the groove 112 may have a cross shape and the carrier block 120 may have a rectangular plate shape, wherein the groove 112 may have an appropriate size to receive the carrier block 120 in any of two orientations (e.g., the X direction or the Y direction). Embodiments of the present disclosure are not limited, and other shapes may be implemented.

The main body portion 110 may include a plurality of grooves 112. The plurality of grooves 112 may be arranged to be spaced apart from each other in a horizontal direction (e.g., the X direction and/or the Y direction) on the lower surface of the plate 111. According to some embodiments, the plurality of grooves 112 may be arranged to be radially symmetrical in the lower surface of the plate 111. Accordingly, the main body portion 110 including the groove 112 may be used in a semiconductor process without distortion. For example, when the carrier block 120 is mounted inside the groove 112, the plurality of grooves 112 may be arranged to form a radially symmetrical pattern on the lower surface of the plate 111 and the main body portion 110 on which the carrier block 120 is mounted may have a uniform coefficient of thermal expansion.

The groove 112 may be formed to have a relatively small size compared to the plate 111. For example, when the groove 112 is formed in a disk-shape and is formed in a disk-shaped plate 111, a plurality of grooves 112 having a diameter less than the diameter of the plate 111 may be formed in the lower surface of the plate 111.

The main body portion 110 one or more grooves 112. For example, one groove 112 may be formed in the lower surface of the plate 111 according to an application.

The main body portion 110 may include a material having a first coefficient of thermal expansion. For example, the main body portion 110 may include silicon, glass, ceramic, organic material, or plastic. The material of the main body portion 110 is not limited thereto, and may include any material that may be used as a carrier substrate.

The carrier block 120 may include a block that may be mounted in the groove 112 formed in the lower surface of the main body portion 110. The carrier block 120 may include a substrate piece that is mounted on the main body portion 110. The carrier substrate 100 may include the main body portion 110 and the carrier block 120.

The carrier block 120 may have a shape and size corresponding to the groove 112 of the main body portion 110. For example, the carrier block 120 may have a disk shape or a square plate shape, and may be formed to have a size allowing the carrier block 120 to be mounted inside the groove 112. The shape of the carrier block 120 is not limited to the disk shape or the square plate shape, and may be formed in shapes corresponding to, or complementing various shapes of the groove 112, such as an elliptical plate or a polygonal plate other than a square, according to an application.

The thickness t3 of the carrier block 120 may have a less value than the thickness t1 of the plate 111. According to some embodiments, the thickness t3 of the carrier block 120 may have a less value than the depth t2 of the groove 112. In this case, the adhesive layer 130 may be disposed in the space between the groove 112 and the carrier block 120. A thickness of the adhesive layer 130 may be dependent on a difference between the depth t2 of the groove 112 and the thickness t3 of the carrier block 120.

The carrier block 120 may be completely inserted and mounted inside the groove 112 of the main body portion 110. For example, when the carrier block 120 is mounted in the groove 112, a lower surface of the carrier block 120 and a lower surface of the plate 111 may be arranged to be positioned at substantially the same vertical level. In other words, since the lower surface of the carrier block 120 and the lower surface of the plate 111 may be formed in substantially the same position in a vertical direction (Z direction), the carrier substrate 100 formed by mounting the carrier block 120 on the main body portion 110 may have a substantially flat lower surface.

The carrier block 120 may be detachably mounted inside the groove 112 of the main body portion 110. For example, during semiconductor processing, the carrier block 120 may be inserted into the groove 112 of the main body portion 110 and bonded to the main body portion 110, and the carrier block 120 may be subsequently removed from the groove 112 of the main body portion 110.

The carrier block 120 may be made of a material having a second coefficient of thermal expansion that is different from the first coefficient of thermal expansion of the main body portion 110. For example, the carrier block 120 may include silicon, glass, ceramic, organic material, or plastic having a coefficient of thermal expansion different from that of the main body portion 110. The material of the carrier block 120 is not limited, and may include any material that may be used as a carrier substrate and may include a material having a coefficient of thermal expansion different from that of the main body portion 110.

According to some embodiments, during semiconductor processing, the carrier substrate 100 including the main body portion 110 and the carrier block 120 may be implemented with various coefficients of thermal expansion. When the carrier block 120 is not mounted on the main body portion 110, a coefficient of thermal expansion of the carrier substrate 100 may have the same value as the first coefficient of thermal expansion of the main body portion 110. When the carrier block 120 is mounted on the main body portion 110, the coefficient of thermal expansion of the carrier substrate 100 may have a value between the first coefficient of thermal expansion of the main body portion 110 and the second coefficient of thermal expansion of the carrier block 120. According to some embodiments, a coefficient of thermal expansion of the carrier substrate 100 may be tuned by using different numbers of the carrier block 120. For example, the carrier block 120 may be mounted in only some of the plurality of grooves 112 formed in the main body portion 110, which may tune the coefficient of thermal expansion of the carrier substrate 100.

For example, the second coefficient of thermal expansion of the carrier block 120 may have a lower value than the first coefficient of thermal expansion of the main body portion 110. In this case, a maximum value of the coefficient of thermal expansion of the carrier substrate 100 may have a value of the first coefficient of thermal expansion of the main body portion 110, and may have a value between the first coefficient of thermal expansion and the second coefficient of thermal expansion when the carrier block 120 is bonded to the main body portion 110.

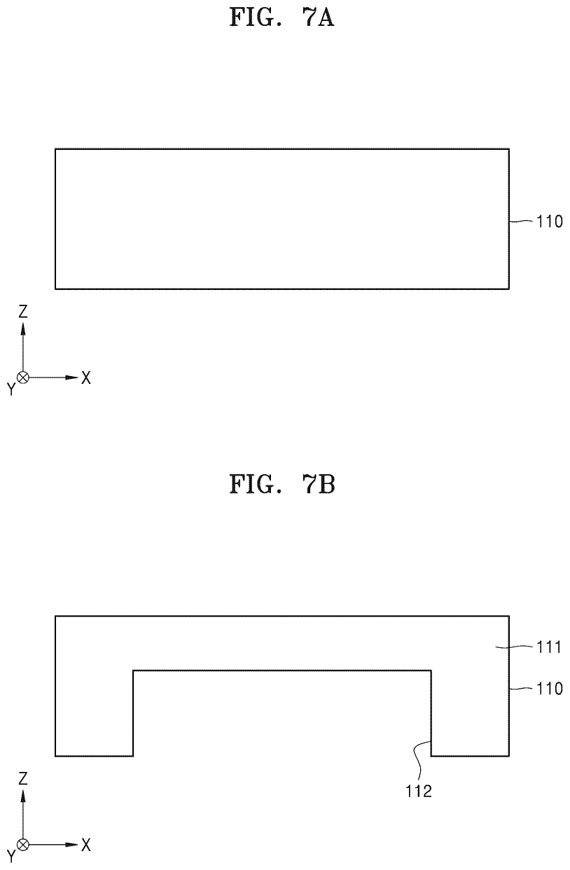

While a case where the second coefficient of thermal expansion of the carrier block 120 has a lower value than the first coefficient of thermal expansion of the main body portion 110 has been described, the inventive concept is not limited thereto. For example, the second coefficient of thermal expansion may have a greater value than the first coefficient of thermal expansion. When the main body portion 110 includes the plurality of grooves 112, a plurality of carrier blocks 120 having different coefficients of thermal expansion may be also mounted in the plurality of grooves 112. For example, the carrier block 120 may include a first carrier block 121 (see FIG. 5B) having a third coefficient of thermal expansion and a second carrier block 122 (see FIG. 5B) having a fourth coefficient of thermal expansion that is different from the third coefficient of thermal expansion. Here, the third coefficient of thermal expansion and the fourth coefficient of thermal expansion may have different values from the first coefficient of thermal expansion. The first carrier block 121 or the second carrier block 122 having a different coefficient of thermal expansion may be mounted in each of the plurality of grooves 112 formed in the main body portion 110. In this case, the carrier block 120 having an appropriate coefficient of thermal expansion may be mounted in or be removed from each groove 112 to inhibit or prevent the warpage of the device substrate 200 during semiconductor processing.

The adhesive layer 130 may fix the carrier block 120 to the inside of the groove 112 of the main body portion 110. The adhesive layer 130 may fill at least a portion of the space between the groove 112 and the carrier block 120 so that the lower surface of the carrier block 120 may be positioned on substantially the same vertical level as the lower surface of the plate 111 of the main body portion 110. The adhesive layer 130 may closely adhere and fix the carrier block 120 to the inside of the groove 112. For example, when the carrier block 120 is mounted in the groove 112, the adhesive layer 130 may provide adhesive force so that the carrier block 120 and the main body portion 110 may operate in an integrated manner. Accordingly, the carrier block 120 may be bonded to the main body portion 110 to form the carrier substrate 100.

Also, the adhesive layer 130 may detachably fix the carrier block 120 to the groove 112. The adhesive layer 130 may provide adhesive force that may allow the carrier block 120 to be detached from the groove 112 when an appropriate force is applied to the main body portion 110 and/or the carrier block 120. During semiconductor processing, the carrier block 120 may be mounted in or detached from the groove 112 using the adhesive layer 130 so that the carrier substrate 100 including the carrier block 120 and the main body portion 110 may implement an appropriate coefficient of thermal expansion according to a current processing. For example, when the carrier block 120 mounted on the main body portion 110 is removed from the main body portion 110, the adhesive layer 130 may be detached from the main body portion 110 together with the carrier block 120. However, the inventive concept is not limited thereto, and when the carrier block 120 is removed from the main body portion 110, a portion of the adhesive layer 130 may remain inside the groove 112 of the main body portion 110.

The adhesive layer 130 may include a material capable of transferring heat between the carrier block 120 and the main body portion 110. For example, the adhesive layer 130 may be formed of thermal interface material (TIM) or thermally conductive resin. The material of the adhesive layer 130 is not limited thereto, and may include a material that may allow the carrier block 120 and the main body portion 110 to operate in an integrated manner and may transfer heat.

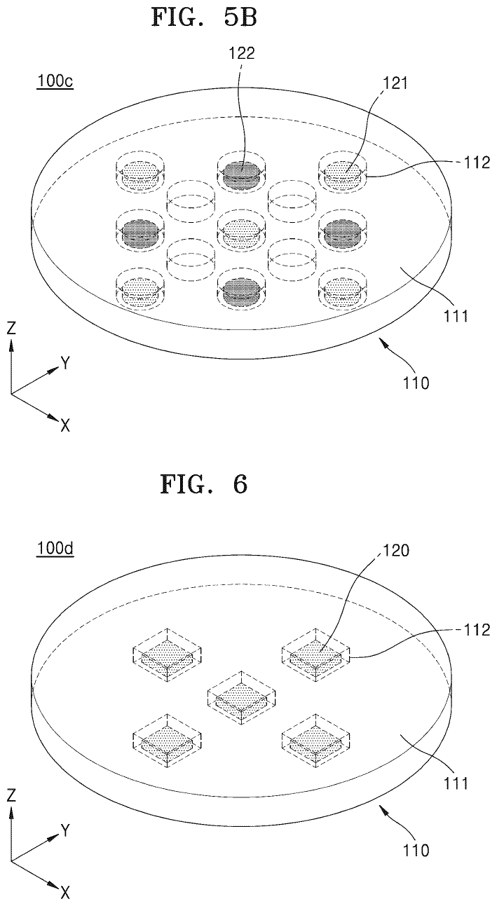

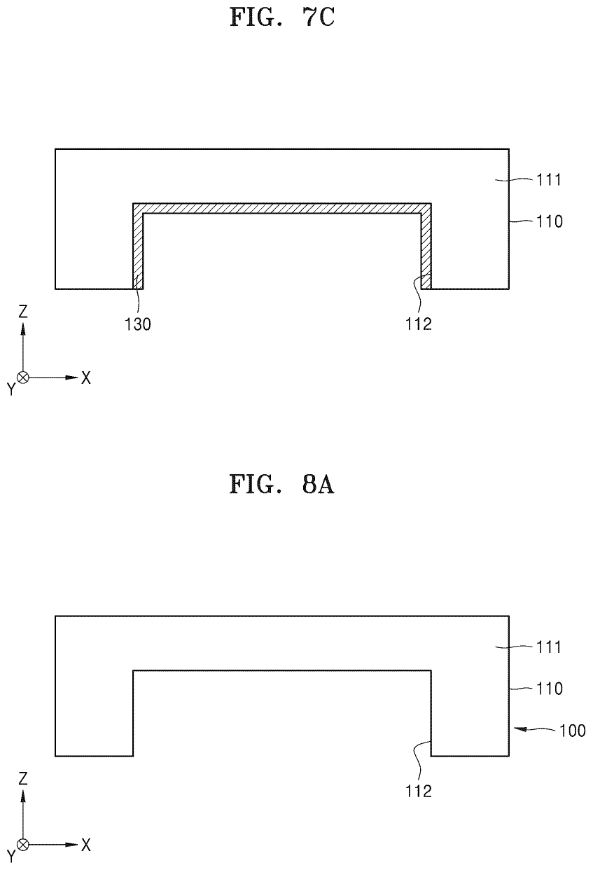

FIG. 4, FIG. 5A, FIG. 5B, and FIG. 6 are perspective views illustrating carrier substrates 100a, 100b, 100c, and 100d according to an embodiment. The carrier substrates 100a, 100b, 100c, and 100d according to some embodiments of FIGS. 4 to 6 may include grooves 112 of various shapes, sizes, and numbers, and carrier blocks 120 corresponding thereto. Similar to FIG. 2, the illustration of the adhesive layer 130 in the carrier substrates 100a, 100b, 100c, and 100d according to some embodiments of FIGS. 4 to 6 may be omitted. Repetitive descriptions of the carrier substrate 100, as described with reference to FIGS. 1 to 3, may be omitted.

Referring to FIG. 4, a main body portion 110 of the carrier substrate 100a according to an embodiment may include one groove 112. The groove 112 may be formed by recessing a lower surface of a plate 111 in a thickness direction (Z direction) of the plate 111. In this case, the groove 112 may be arranged in a center portion of the lower surface of the plate 111, which may inhibit or prevent the distortion of the carrier substrate 100a. According to some embodiments, the groove 112 formed in the carrier substrate 100a of FIG. 4 may have a relatively large diameter. In FIG. 4, the carrier block 120 of a disk shape and the groove 112 of a shape corresponding thereto are illustrated, but the present disclosure is not limited thereto, and the carrier substrate 100a may include the groove 112 having different shapes and the carrier block 120 may correspond thereto.

Referring to FIG. 5A, the carrier substrate 100b according to an embodiment may include a plurality of grooves 112 and a plurality of carrier blocks 120. FIG. 5A is an exemplary illustration, and the carrier substrate 100b may include various numbers of grooves 112. As described herein, when the carrier substrate 100b includes a plurality of grooves 112, the respective grooves 112 may be arranged to be spaced apart from each other and radially symmetrical to each other on a lower surface of a plate 111.

The carrier block 120 may be mounted in each groove 112. The carrier block 120 having a second coefficient of thermal expansion different from a first coefficient of thermal expansion of a main body portion 110 may be mounted in each groove 112. According to an embodiment, as illustrated, the carrier blocks 120 may be also mounted only in one or more of the grooves 112. For example, the carrier blocks 120 may be mounted less than all the plurality of grooves 112 formed in the main body portion 110, and the carrier blocks 120 may be mounted so that the carrier blocks 120 may be radially symmetrical to each other. By mounting the carrier blocks 120 less than all of the grooves 112, the carrier substrate 100b having a coefficient of thermal expansion tuned during processing.

Referring to FIG. 5B, the carrier substrate 100c according to an embodiment may include a plurality of grooves 112, and first carrier blocks 121 and second carrier blocks 122 having different coefficients of thermal expansion may be mounted in the respective grooves 112. For example, the first carrier block 121 having a third coefficient of thermal expansion different from a first coefficient of thermal expansion, and the second carrier block 122 having a fourth coefficient of thermal expansion different from the first coefficient of thermal expansion and the third coefficient of thermal expansion may be mounted in the respective grooves 112. According to an embodiment, as illustrated, the first carrier block 121 or the second carrier block 122 may be also mounted in one or more of the grooves 112. In FIG. 5B, it is illustrated that the carrier substrate 100c includes the first carrier block 121 and the second carrier block 122, but the present disclosure is not limited thereto, and may further include additional carrier blocks having different coefficients of thermal expansion.

Referring to FIG. 6, the carrier substrate 100d according to an embodiment may include a carrier block 120 having a square plate shape and a groove 112 corresponding thereto. According to some embodiments, the groove 112 corresponding to the carrier block 120 of the square plate shape may be arranged to be spaced apart and radially symmetrical in the main body portion 110. In FIG. 6, it is illustrated that the carrier substrate 100d includes the carrier block 120 having a square bottom surface and the groove 112 corresponding thereto, but the present disclosure is not limited thereto. For example, the carrier substrate 100d may also include a carrier block 120 having a rectangular shape with a different a width and length, and a groove 112 corresponding thereto. Furthermore, the carrier substrate 100d may include a carrier block 120 having an oval plate shape and a groove 112 corresponding thereto, or a carrier block 120 having a polygonal plate shape other than a square and a groove 112 corresponding thereto. In an further example, the carrier block 120 may have a stepped shape in the Z direction, and the groove 112 may have a stepped shape corresponding thereto.

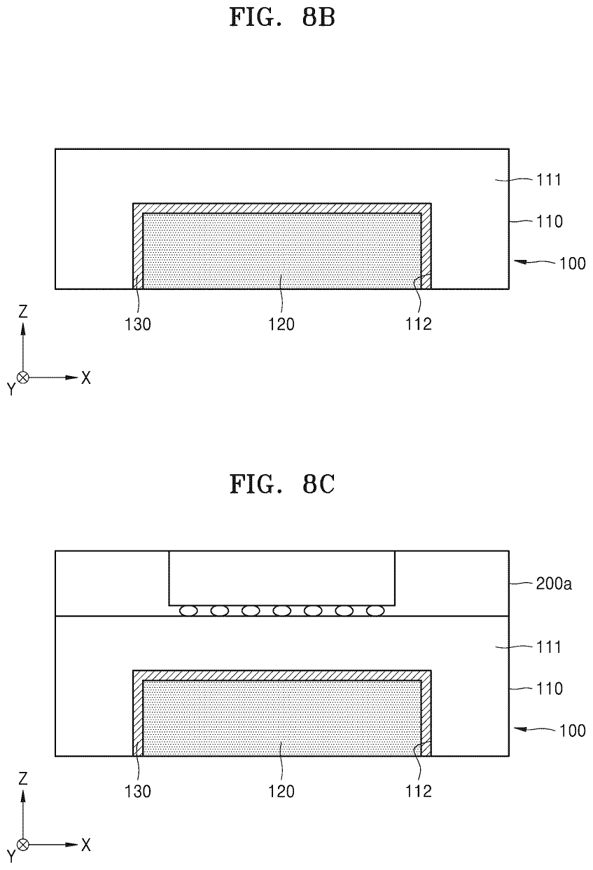

FIG. 7A, FIG. 7B, and FIG. 7C are partial cross-sectional views schematically illustrating a method of manufacturing the carrier substrate 100 according to an embodiment.

Referring to FIGS. 7A and 7B, a main body portion 110 including a plate 111 and a groove 112 may be prepared. The groove 112 may be formed in a lower surface of the plate 111 constituting the main body portion 110. The main body portion 110 may be made of, for example, silicon, glass, ceramic, organic material, or plastic. The main body portion 110 may have a first coefficient of thermal expansion. The groove 112 may be formed by recessing the lower surface of the plate 111 in a thickness direction (Z direction) of the plate 111. The groove 112 may be formed through, for example, an etching process. However, the process of forming the groove 112 is not limited to the etching process. For example, the groove 112 may be formed through laser drilling. The groove 112 may be formed in the lower surface of the plate 111 toward an upper surface of the plate 111 so as not to penetrate through the plate 111. A plurality of grooves 112 may be formed to be spaced apart from each other in the lower surface of the plate 111.

Referring to FIG. 7C and FIG. 3, the carrier block 120 may be disposed in the groove 112 of the main body portion 110. According to some embodiments, the adhesive layer 130 may be disposed on a surface of the groove 112 of the main body portion 110, and the carrier block 120 may be inserted and mounted inside the groove 112. The adhesive layer 130 may provide adhesive force for fixing the carrier block 120 to the inside of the groove 112. The carrier block 120 may be adhered and fixed to the inside of the groove 112 through the adhesive layer 130.

The carrier block 120 may have a second coefficient of thermal expansion that is different from the first coefficient of thermal expansion of the main body portion 110. When the carrier block 120 is mounted inside the groove 112, a lower surface of the carrier block 120 and the lower surface of the plate 111 may be disposed to be positioned on substantially the same vertical level, and the adhesive layer 130 may provide adhesive force enabling the carrier block 120 and the main body portion 110 to constitute the carrier substrate 100 as an integrated unit. According to an embodiment, the carrier block 120 may be bonded to, and debonded from the main body portion 110 as needed.

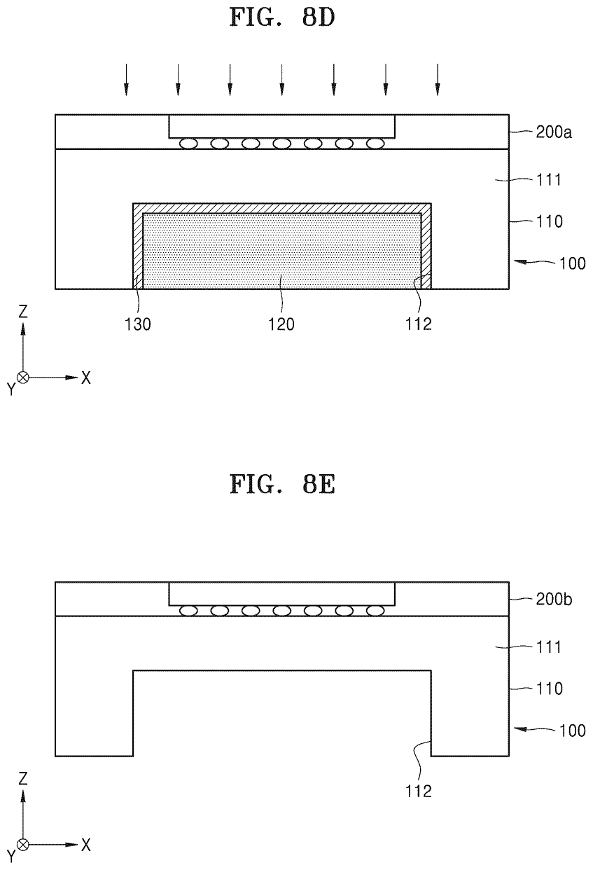

FIG. 8A, FIG. 8B, FIG. 8C, FIG. 8D, and FIG. 8E are partial cross-sectional views schematically illustrating a carrier substrate 100 supporting a device substrate 200 in a method of manufacturing a semiconductor package according to an embodiment.

Depending on a semiconductor package manufacturing process, a coefficient of thermal expansion of the device substrate 200 (see FIG. 1) on which the process may be performed may change. By using the carrier substrate 100 having the same coefficient of thermal expansion as the device substrate 200, the occurrence of warpage of the device substrate 200 due to a difference of a coefficient of thermal expansion between the carrier substrate 100 and the device substrate 200 may be inhibited or prevented. Accordingly, a carrier block 120 may be mounted on, or detached from the main body portion 110 and the carrier substrate 100 may be tuned to have a coefficient of thermal expansion appropriate for processing.

Referring to FIG. 8A, the carrier substrate 100 formed according to the process of FIGS. 7A and 7B may be prepared. The carrier substrate 100 may include the main body portion 110 having a first coefficient of thermal expansion, and the main body portion 110 may include a plate 111 and a groove 112 formed on a lower surface of the plate 111.

Referring to FIG. 8B, the carrier block 120 having a second coefficient of thermal expansion may be disposed on the main body portion 110 of the carrier substrate 100 according to the process of FIG. 7C and FIG. 3. The carrier block 120 may be fixed to the inside of the groove 112 through an adhesive layer 130. The adhesive layer 130 may be disposed inside the groove 112 of the main body portion 110, and the carrier block 120 may be inserted and fixed to the inside of the groove 112 where the adhesive layer 130 is disposed.

Referring to FIG. 8C, a device substrate 200a may be disposed on the carrier substrate 100. The device substrate 200a may be supported on the upper surface of the plate 111.

Referring to FIG. 8D, a semiconductor process may be performed on the device substrate 200a mounted on the carrier substrate 100. For example, a back grinding process for thinning the device substrate 200a may be performed. In FIG. 8D, it is illustrated that the back grinding process is performed on the device substrate 200a, but the present disclosure is not limited thereto, and various semiconductor processes such as a redistribution process, an exposure process and development process using photoresists may be performed, or a plating process may be performed. The carrier block 120 having the second coefficient of thermal expansion may be disposed on the main body portion 110 having the first coefficient of thermal expansion, and a coefficient of thermal expansion of the carrier substrate 100 may be tuned to correspond to a coefficient of thermal expansion of the device substrate 200a at a corresponding stage.

For example, the main body portion 110 having a first coefficient of thermal expansion of 7 and the carrier block 120 having a second coefficient of thermal expansion of 3 may be used. In process operations illustrated in FIGS. 8C and 8D, when the coefficient of thermal expansion of the device substrate 200a is equal to 5, the carrier substrate 100 having a coefficient of thermal expansion of 5 may be implemented by bonding the carrier block 120 to the main body portion 110. That is, the average of the first coefficient of thermal expansion of 7 and the second coefficient of thermal expansion of 3 is equal to 5. For example, the main body portion 110 and the carrier block 120 may have a combined coefficient of thermal expansion corresponding to the device substrate 200a. In this case, the adhesive layer 130 may transfer heat between the carrier block 120 and the main body portion 110, and may provide adhesive force so that the carrier block 120 may operate integrally with the main body portion 110.

In a semiconductor package manufacturing method operation of FIG. 8E, one or more instances of the carrier block 120 (see FIG. 8D) may be removed, added, or replaced from the carrier substrate 100 in response to a coefficient of thermal expansion of the device substrate 200b that is changed according to the process of FIG. 8D. An additional semiconductor process may be performed on the device substrate 200b of FIG. 8E.

For example, in a process operation illustrated in FIG. 8E, when the coefficient of thermal expansion of the device substrate 200b is equal to about 7, the carrier block 120 may be detached from the main body portion 110. The carrier substrate 100 from which all the carrier blocks 120 have been removed may have the same coefficient of thermal expansion of 7 as the main body portion 110. The adhesive layer 130 may detachably fix the carrier block 120 to the groove 112 so that the carrier block 120 may be mounted on or removed from the main body portion 110 during semiconductor processing as described herein.

The carrier substrate 100 according to an embodiment may adjust a coefficient of thermal expansion for the purpose of warpage control for a given a semiconductor process. By using the main body portion 110 and the carrier block 120 having different coefficients of thermal expansion, the carrier substrate 100 according to an embodiment may bond the carrier block 120 to, or debond the carrier block 120 from the main body portion 110 according to processing and provide a tuned coefficient of thermal expansion. Therefore, a carrier substrate 100 may be tuned to correspond to a coefficient of thermal expansion needed during a process, and may inhibit or prevent warpage throughout one or more processes.

The carrier substrate 100 according to an embodiment is not limited to examples described herein, and may include the carrier block 120 having various materials, shapes, sizes, numbers, and coefficients of thermal expansion, and the main body portion 110 having the grooves 112 corresponding thereto.

Embodiments of the inventive concept have been described with reference to the drawings, but these are merely illustrative, and those skilled in the art will understand that various modifications and other equivalent embodiments are possible therefrom. Therefore, the true scope of technical protection of the inventive concept should be defined by the technical spirit of the attached claims.

While the inventive concept has been particularly shown and described with reference to embodiments thereof, it will be understood that various changes in form and details may be made therein without departing from the spirit and scope of the following claims.

What is claimed is:

1. A carrier substrate comprising:
a main body portion that comprises a plate having an upper surface and a lower surface disposed opposite to the upper surface, and a groove formed in the lower surface of the plate, the main body portion having a first coefficient of thermal expansion; and
a carrier block detachably mounted in the groove and having a second coefficient of thermal expansion different from the first coefficient of thermal expansion.

2. The carrier substrate of claim 1, wherein the groove is formed by recessing the lower surface of the plate in a thickness direction of the plate.

3. The carrier substrate of claim 1, wherein the main body portion comprises a plurality of grooves, and
the plurality of grooves are arranged spaced apart from each other on the lower surface of the plate.

4. The carrier substrate of claim 3, wherein the plate has a disk shape, and
the plurality of grooves are arranged radially symmetrical to each other on the lower surface of the plate.

5. The carrier substrate of claim 3, wherein the carrier block comprises:
a first carrier block having the second coefficient of thermal expansion that is different from the first coefficient of thermal expansion; and
a second carrier block having a third coefficient of thermal expansion that is different from the first coefficient of thermal expansion and the second coefficient of thermal expansion, and
the first carrier block and the second carrier block are mounted in the plurality of grooves.

6. The carrier substrate of claim 3, wherein the carrier block is mounted in less than all of the plurality of grooves.

7. The carrier substrate of claim 1, wherein a thickness of the carrier block is less than a thickness of the plate.

8. The carrier substrate of claim 1, wherein the carrier block is disposed inside the groove and includes a lower surface, and the lower surface of the carrier block is disposed at a same vertical level as the lower surface of the plate.

9. The carrier substrate of claim 1, wherein the first coefficient of thermal expansion has a greater value than the second coefficient of thermal expansion.

10. The carrier substrate of claim 1, further comprising an adhesive layer disposed in the groove and configured to fix the carrier block to an inside of the groove,
wherein the adhesive layer adheres and fixes the carrier block to the inside of the groove, and the main body portion and the carrier block operate in an integrated manner.

11. The carrier substrate of claim 1, further comprising an adhesive layer disposed in the groove and configured to fix the carrier block to an inside of the groove,
wherein the adhesive layer comprises a material transferring heat between the carrier block and the main body portion.

12. The carrier substrate of claim 1, wherein the main body portion comprises one of silicon, glass, ceramic, organic material, or plastic.

13. The carrier substrate of claim 1, wherein the groove has a shape corresponding to the carrier block, and
the carrier block has the shape of a disk plate, an elliptical plate, a square plate, a rectangular plate, a polygonal plate, or a cross plate.

14. A carrier substrate comprising:
a main body portion that comprises a plate configured to support a device substrate disposed on an upper surface of the plate and a plurality of grooves arranged radially symmetrical to each other on a lower surface of the plate disposed opposite to the upper surface of the plate, the plurality of grooves being recesses in the lower surface of the plate in a thickness direction of the plate, the main body portion having a first coefficient of thermal expansion;
a plurality of carrier blocks disposed in the plurality of grooves, respectively, and having a second coefficient of thermal expansion less than the first coefficient of thermal expansion; and
an adhesive layer configured to fix the plurality of carrier blocks inside of the plurality of grooves.

15. The carrier substrate of claim 14, wherein a thickness of the plurality of carrier blocks is less than a thickness of the plate,
the plurality of carrier blocks are mounted inside the plurality of grooves so that lower surfaces of the plurality of carrier blocks are positioned at a same vertical level as a lower surface of the plate, and
the adhesive layer detachably fixes the plurality of carrier blocks to an inside of the plurality of grooves.

16. A method of manufacturing a semiconductor package by using a carrier substrate, the method comprising:
preparing a carrier substrate comprising a main body portion that comprises a plate configured to support a device substrate on an upper surface of the plate and a groove formed in a lower surface of the plate, the main body portion having a first coefficient of thermal expansion;
mounting the device substrate on the upper surface of the plate; and
mounting, in the groove of the main body portion, a carrier block having a second coefficient of thermal expansion different from the first coefficient of thermal expansion, wherein the main body portion and the carrier block have a combined coefficient of thermal expansion corresponding to a coefficient of thermal expansion of the device substrate.

17. The method of claim 16, further comprising, before the mounting of the carrier block in the groove,
disposing an adhesive layer inside the groove.

18. The method of claim 16, further comprising performing a semiconductor process on the device substrate.

19. The method of claim 16, further comprising removing the carrier block from the main body portion.

20. The method of claim 16, wherein
the main body portion comprises a plurality of grooves, and
the plurality of grooves are arranged spaced apart from each other on the lower surface of the plate.
